(19) United States
(12) Patent Application Publication
(10) Pub. No.: US 2021/0265137 A1
(43) Pub. Date: Aug. 26, 2021

(54) RECONDITIONING OF REACTIVE PROCESS CHAMBER COMPONENTS FOR REDUCED SURFACE OXIDATION

(71) Applicant: Intel Corporation, Santa Clara, CA (US)

(72) Inventors: Jeffrey Young, San Francisco, CA (US); Patrick Whiting, Beaverton, OR (US); David Laube, Mesa, AZ (US)

(73) Assignee: Intel Corporation, Santa Clara, CA (US)

(21) Appl. No.: 17/171,894

(22) Filed: Feb. 9, 2021

Related U.S. Application Data
(60) Provisional application No. 62/981,995, filed on Feb. 26, 2020.

(51) Int. Cl. H01J 37/32; B08B 3/08

(52) U.S. Cl. CPC H01J 37/32495; H01J 37/32357; H01J 2237/334; B08B 3/08; H01J 37/3244

(57) ABSTRACT

Following use of a reactive process chamber, a component of the chamber, such as an edge ring that is to surround a workpiece during an etching process, may be refurbished through one or more residue removal operations followed by a surface texturing operation. The texturing operation may entail media blasting with a gaseous media propellant comprising a smaller fraction of O₂ than air, such as high purity dry N₂. The more inert gaseous media propellant may advantageously control oxygen contamination of a bulk metal, such as aluminum. Reconditioning may further entail a chemical treatment, which thins or completely removes, a surface oxide present after the texturing operation. The conditioned surface may then have a surface composition and texture that is capable of matching the performance of a previously unused chamber component.

### CLAIM OF PRIORITY

This application claims priority to Provisional Patent Application No. 62/981,995, filed on Feb. 26, 2020 and titled “RECONDITIONING OF REACTIVE PROCESS CHAMBER COMPONENTS FOR REDUCED SURFACE OXIDATION,” which is incorporated herein by reference in its entirety.

### BACKGROUND

Various features of microelectronic devices may be fabricated within a reactor, or reactive processing chamber. Subtractive processes, such dry etch, or plasma etch, may be performed with such a reactive processing chamber. Such reactive processing chambers may be referred to as etch process chambers, or simply etch modules. Typically, a workpiece, such as a wafer (e.g., comprising a semiconductor or other substrate material) is placed on a chuck or platen and exposed to a reactive species generated as a result of energizing a plasma of a feed gas. In some configurations, a plasma may be generated remotely of the chamber in which a workpiece resides. Such, remote plasma etch systems may be favored for transporting radicals, rather than ions, to the workpiece surface. Such radicals may not only react with the features on the workpiece, but may also react with surfaces in the surrounding environment (e.g., process chamber components).

During workpiece processing, a chemical residue may form on exposed surfaces of various reactor chamber components as the radicals react with the process chamber components. Over time, as more workpieces are processed, the residue may induce a process parameter drift that eventually becomes detrimental to workpiece processing. The chamber components may therefore need to be periodically removed from the chamber and cleaned. For example, a rate at which radicals etch features, or a cleanliness of the chamber, may gradually become unacceptable for workpiece processing. However, cleaning a used reactive process chamber component may alter the reactor chamber component surface relative to a brand new, unused, component. Such changes may impact an interaction of etchant species (e.g., radicals) with the reactor chamber component so that there is another shift in one or more parameters associated with the workpiece processing. For example, the rate at which radicals may etch features over an area of the workpiece may vary between an unused chamber component and one that has been cleaned following a prior use. This complexity may deter the reuse of chamber components resulting in a higher consumables costs for workpiece processing.

### BRIEF DESCRIPTION OF THE DRAWINGS

Embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 schematically illustrates a cross-sectional view of reactive processing chamber, where a surface of a reactive processing chamber component acquires a residue with system usage, and where the chamber component is to be reused after an ex-situ refurbishment that is to remove the residue and recover a surface equivalent to that of an unused or new component, in accordance with some embodiments.

FIG. 2 illustrates a flowchart depicting methods for processing workpieces with a reactive process chamber including components that are refurbished, in accordance with some embodiments.

FIG. 3 illustrates a flowchart depicting methods for reconditioning a reactive process chamber component, in accordance with some embodiments.

FIG. 4A illustrates element concentration profiles for a component cleaned of residue according to a conventional method;

FIG. 4B illustrates element concentration profiles for a component cleaned of residue in accordance with some embodiments;

FIG. 5 illustrates an exemplary system suitable for implementing, at least in part, the method shown in FIG. 3, in accordance with some embodiments.

### DETAILED DESCRIPTION

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices.

The meanings of “a,” “an,” and “the” include plural references. The meaning of “in” includes “in” and “on.” The terms “substantially,” “close,” “approximately,” “near,” and “about,” generally refer to being within +/−10% of a target value.

Unless otherwise specified the use of the ordinal adjectives “first,” “second,” and “third,” etc., to describe a same object, merely indicate that different instances of like objects are being referred to, and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C). The terms “left,” “right,” “front,” “back,” “top,” “bottom,” “over,” “under,” and the like in the description and in the claims, if any, are used for descriptive purposes and not necessarily for describing permanent relative positions.

Within a processing chamber, a chamber component may be exposed to various reactive species, such as chemical radicals. Surface texture, or other morphological characteristics, may be important for a chamber component. For example, surface roughness (or area) may impact some chamber component's rate of reaction with species generated within the processing environment. In some instances however, the inventors have found morphological characteristics, such as surface texture, are poorly correlated to chamber process performance. This may be particularly true for certain chamber components that are in close proximity to a workpiece and can therefore have a large impact on processing (e.g., etching) of a workpiece. The inventors have further found that the thickness of a surface oxide on a component can be strongly correlated to a chamber's workpiece processing performance. Hence, in accordance with embodiments herein a chamber component may be refurbished so as to have a desired surface chemical composition as well as a desired surface texture (or surface area).

In some embodiments, a chamber component may be cleaned, for example to remove processing residue (e.g., from workpiece etching), so that surface oxide of the cleaned component is substantially the same as that of a component in “new” or “unused” condition. Additionally, or in combination, a chamber component may be cleaned so that both the surface oxide and the surface morphology of the cleaned component are substantially the same as those of the component in new/unused condition. Interactions between the chamber component and reactive species of the processing environment (e.g., chemical radicals) may be maintained when surface conditioning ensures both a chemical and morphological match to a new component. For exemplary microelectronic device etching embodiments, the cleaning process can be assured to avoid impacting the etch rate of features on a workpiece. With stable etch rates, a chamber component may be repeatedly refurbished and reused for workpiece processing.

Oxygen contamination is one mechanism by which the chemical composition of a chamber component's surface may vary as a result of reconditioning the component. Depending on the component reconditioning process, oxygen contamination on a metal component surface, for example, may vary significantly. The inventors have found these different levels of component surface oxidation can contribute to performance deviations in a reactive etch process. Similar effects may also be expected in various other reactive chamber processes, such as chemical vapor deposition (CVD) or atomic layer deposition (ALD).

For chamber components comprising a bulk metal, the metal surface may have some passivation material, such as a “native” oxide that is generated during initial manufacture of the component, for example through an oxidation of the bulk metal surface under some controlled condition. As further described below, the inventors have found that cleaning process residue from the component can leave the component surface in a state that is altered from that of a new, unused component. For example, reconditioning processes resulting in substantially more surface oxidation than what is found on a new/unused component can be sufficiently detrimental to the workpiece processing that the use of refurbished components may not be possible.

Refurbishment methods in accordance with embodiments herein may provide a desirable surface chemical composition on a refurbished component by controlling the amount of oxidation the component undergoes during refurbishment. With these methods the component surface chemistry/composition may be better matched to an original operational state. An etch process chamber, for example, may therefore have etch rates before and after refurbishment of the component that are closely matched. The higher costs, higher environmental impact, and intrinsic supply chain risks associated with a reliance upon new replacement components may thereby be mitigated.

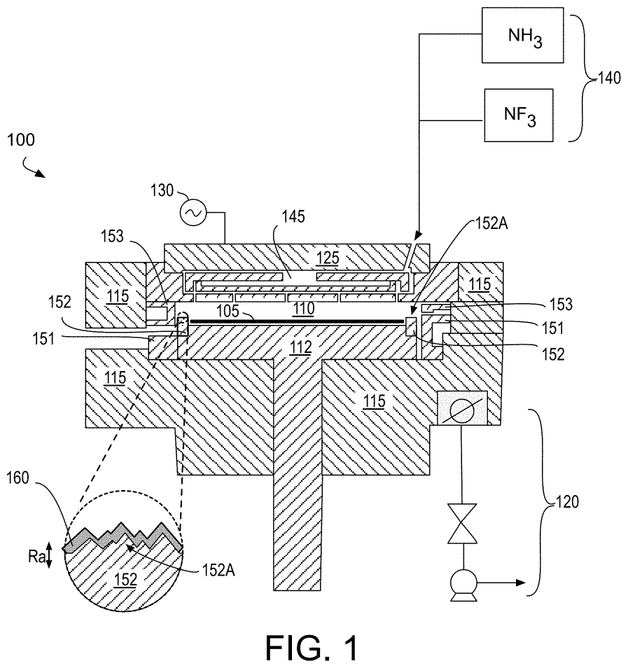

FIG. 1 schematically illustrates a reactive processing chamber (i.e., reactor) 100 in a partial cross-sectional view. Various components of processing chamber 100 are symbolically illustrated in FIG. 1, without illustrating the exact shape, size, location or other details of the various components. In the illustrated example, reactive processing chamber 100 is a etch process chamber, reactor, or module. Processing chamber 100 may be any appropriate reactor for etching microelectronics devices, such as a vacuum dry etch reactor. However, the principles of this disclosure may also be applied to any type of reactor that employs a plasma for etching workpieces.

Processing chamber 100 includes a chamber body 115, a lid assembly including an electrode 125 that is electrically coupled to a power source 130. Power source 130 may be any source, such as, but not limited to a radio frequency (RF), direct current (DC), or microwave (MW) generator. In the illustrated example, electrode 125 is located at an upper end of chamber body 115, and a workpiece support assembly 112 is at least partially disposed within a lower end of chamber body 115. Processing chamber 100 and the associated hardware may be of one or more process-compatible structural materials (e.g. aluminum, stainless steel, etc.).

Chamber body 115 may accommodate a slit valve opening to provide access to a workpiece processing region 110 where a workpiece 105 is to reside during processing. The slit valve opening may be opened and closed to allow access to workpiece processing region 110, for example by handling robot (not shown). Workpiece 105 (e.g., a wafer comprising microelectronic device features) rests over a platen region of workpiece support assembly 112.

Processing chamber 100 is coupled to source gases 140 that are to be introduced into a remote plasma region 145. In the illustrated example, source gases 140 include a hydrogen-containing precursor (e.g., NH₃) and a fluorine-containing precursor (e.g., NF₃). Source gases 140 may further include other gases, such as inerts (e.g., He), or other reactive gases. Source gases 140 are excited into a plasma by power source 130. In this example, remote plasma region 145 is contained within a lid assembly with the hydrogen source gas and fluorine source gas to both flow into remote plasma region 145. Reactive plasma effluents (e.g., chemical radicals) created within remote plasma region 145 are then to travel into workpiece processing region 110 where they interact with workpiece 105 (e.g., etching microelectronic features thereon). Processing chamber 100 is pumped down below atmospheric pressure by a vacuum system 120 that includes a vacuum pump stack downstream of a throttle valve to regulate flow of gases through remote plasma region 145 and workpiece processing region 110.

In addition to interacting with the workpiece 105, reactive species within workpiece processing region 110 may also interact with any chamber component downstream of power source 130. Within processing chamber 100, a residue of process byproducts may collect, buildup, or otherwise form upon chamber components as workpieces are processed within processing chamber 100. An edge-ring 152 is one example of a chamber component that surrounds a perimeter edge of workpiece 105. Edge-ring 152 may be seated within a detent in workpiece support assembly 112 with a top surface 152A exposed to the workpiece processing region 110. Notably, top surface 152A is at or above a top surface of workpiece 105. This proximity makes top surface 152A highly relevant to the processing environment to which workpiece 105 is exposed. Edge-ring 152 is annulus having an inner diameter to surround the platen portion of assembly 112. Edge-ring 152 has an outer diameter sufficient for top surface 152A to be laterally adjacent to a perimeter edge of workpiece 105 during the etching process.

One or more liner components 151, 153 may further surround the workpiece support assembly 112, and/or define workpiece processing region 110. Edge-ring 152 and liner components 151, 153 are preferably removable for servicing and cleaning. Edge-ring 152 and liner components 151, 153 can be made of any process compatible material. Surfaces of each of these components that are exposed to the processing environment may be textured, for example to have some average roughness value Rₐ (or surface area value) as shown for edge-ring 152 in the expand view inset of FIG. 1. Although average roughness value Rₐ may vary, in some embodiments it is in the range of 40-250 pin. Such surface texture, may, for example, increase adhesion of a process byproduct residue 160 that deposits over time as workpiece 105 is processed. The surface texture may thereby prevent flaking of residue 160, which could otherwise contaminate workpiece processing region 110.

In some embodiments, chamber components, such as one or more of edge-ring 152 and liner components 151, 153, are of a bulk metal (e.g., stainless steel, aluminum, nickel, titanium, etc.), a bulk ceramic (e.g., alumina (Al₂O₃), Yttria (Y₂O₃), etc.), or a bulk oxide (e.g., fused quartz), etc. In some further embodiments, a surface of liner components 151, 153, or edge-ring 152, or any other chamber component that comes in contact with the reactive species, may be of a bulk material coated with another material layer (e.g., aluminum coated with a ceramic or an (anodic) oxidation layer). Such a surface coating may, or may not, react with the reactive species during processing of workpiece 105.

In some examples where one or more of edge-ring 152 and liner components 151, 153 are a bulk metal (e.g., predominantly aluminum) without deposited or anodic oxidation layer, these uncoated components may be self-passivated by a native oxide, which is significantly less substantial than a passivation developed through an anodization coating process. In contrast to an anodized aluminum component, an original equipment manufacturer of processing chamber 100 may specify an uncoated aluminum chamber component to have some atomic concentration profile as a function of depth from a surface of the component. This atomic concentration profile specification may be referred to as a “native” or “new” surface oxide condition that is associated with, and/or results from, the process(es) employed in the original manufacture of the uncoated component.

Being uncoated, the degree to which reactive species will interact with the component may depend upon an extent of surface oxide (e.g., alumina) formed on the component surface during a refurbishment process. A refurbishment process that increases the amount of oxygen contamination in a component beyond the original manufacture's specification may modulate (either decrease or increase) an etch (or deposition) rate (average and/or uniformity) on workpiece 105. For example, the concentration of reactive species (e.g., chemical radicals) introduced into workpiece processing region 110 may be depleted more or less through chemical interactions with oxygen present within chamber components, such as one or more of edge-ring 152 and liner components 151, 153. This environmental interaction may impact reaction etch rates of features on workpiece 105.

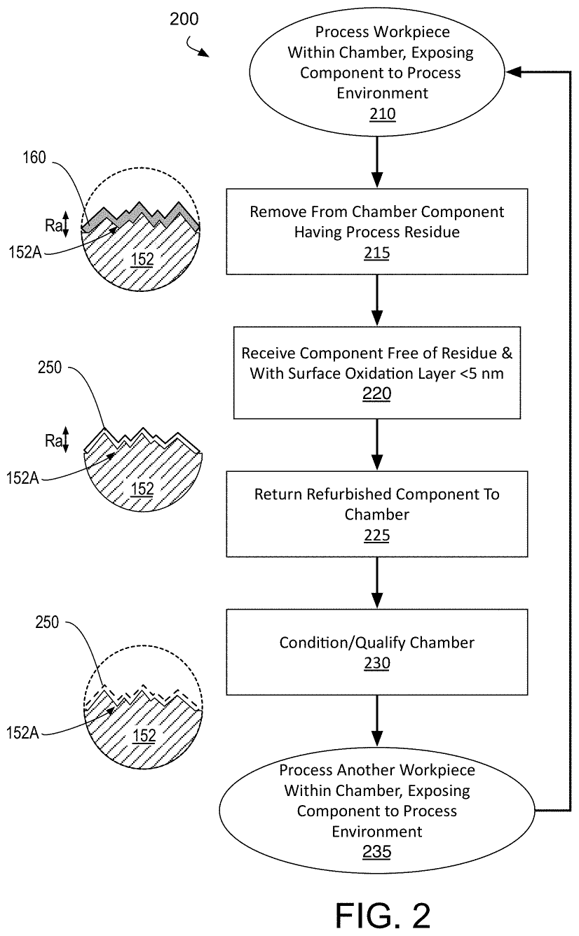

Periodically, chamber components may be removed from reactor 100. Components removed may be replaced with new/unused components that will have substantially the same “as-new” surface morphology and chemical composition as the component removed possessed prior to its repeated use in processing chamber 100. Alternatively, one or more of more of edge-ring 152 or liner components 151, 153 may be replaced with components that have been refurbished in accordance with embodiments herein. FIG. 2 illustrates a flowchart depicting methods 200 for processing workpieces with a reactive process chamber including components that are refurbished, in accordance with some embodiments. A user of a processing chamber 100 may practice methods 200, for example.

Methods 200 begin at block 210 wherein a workpiece is processed within a reactive processing chamber, such as processing chamber 100 (FIG. 1), for example. Within the processing chamber, a reactive process, such as a plasma etch process, and more specifically a remote plasma etch process, is performed on a workpiece. One or more chamber components (e.g., edge-ring 152 or liner components 151, 153 in FIG. 1) are exposed to a reactive process that forms residue (e.g., residue 160) comprising one or more process byproducts on a surface of the exposed chamber components (e.g., surface 152A of edge-ring 152). In some etch process embodiments, residue 160 comprising fluorine is formed on the chamber components(s) at block 210. In some specific embodiments where a chamber component (e.g., edge-ring 152 or liner components 151, 153) comprises aluminum either in bulk form or with a native alumina passivation, etc.), a residue of a fluorine-based etch (e.g., NH₄F radical) may comprise both aluminum and fluorine (e.g., as AlF generated through a chemical reaction between aluminum in the component and the reactive etch species). Such an etch residue can be difficult to remove by in-situ chamber cleaning alone, so after some predetermine process time and/or number workpieces processed, methods 200 continue at block 215 where chamber components having residue 160 thereon are removed from the reactive processing chamber.

Methods 200 continue at block 220 where one or more reconditioned and/or refurbished chamber components are received. In exemplary embodiments, the refurbished chamber component(s) are substantially free of any of residue 160 (having been appropriately cleaned). Furthermore, the refurbished chamber component has a surface oxide 250 that is substantially the same as a new component. Advantageously, the refurbished chamber component received at block 220 has a surface oxide 250 comprising more oxygen than bulk metal. For example, surface oxide 250 may have a higher concentration of oxygen than aluminum. In some such embodiments, on a refurbished chamber component received at block 220 a bulk of the component (e.g., under surface oxide 250) has a higher aluminum concentration than oxygen. Surface oxide 250 may have an atomic percentage oxygen and/or aluminum specified at a predetermined threshold. Alternatively, it may be specified that there be a cross-over point where the aluminum concentration goes from being less than, to greater than, the oxygen concentration. Surface oxide 250 may be controlled to such a specification, for example, through the use of a material characterization technique such as sputter profile Auger Electron Spectroscopy (AES).

As noted above, components may have a particular morphology, quantified through one or more parameter values such as a roughness value (e.g., average roughness Rₐ, roughness range, etc.) or a surface area value (e.g., mean surface area, etc.). In further embodiments, the one or more reconditioned and/or refurbished chamber components received at block 220 have substantially the same morphology characteristic as specified for a new part. For example, a surface oxide on a refurbished component received at block 220 may have a roughness value that is within a predetermined threshold (e.g., +/−10%, +/−20%, etc.) of the roughness value specified for a new component. Advantageously, the roughness value of the refurbished component received at block 220 may be at least equal to the first roughness value (e.g., Rₐ of 40 μin, or more). Surface morphology may be determined with a material characterization technique such as laser scanning microscopy where a region of the component surface may be magnified a predetermined number of times (e.g., 1000-4000×), and a surface area of that region determined for the associated magnification specified to match a new component to at least the threshold.

Methods 200 continue a block 225 where the refurbished component is returned to the reactive processing chamber. At block 230, the processing chamber may then be conditioned and/or qualified to process additional workpieces. The conditioning process at block 230 may include remote plasma generation with fluorine-based chemistry (e.g., generating a NH₄F radical, and/or other radicals). In some embodiments, the conditioning process may remove surface oxide 250, or alternatively, surface oxide 250 may remain throughout the subsequent operation of the chamber. Surface oxide 250 is illustrated in dashed line to emphasize that in some embodiments, conditioning and/or subsequent use of the processing chamber may substantially remove surface oxide 250 from exposed component surfaces (e.g., surface 152A). For such embodiments, workpieces may be processed while the component surface 152A is substantially a bulk metal (e.g., Alₓ).

Once requalified, the chamber may then be returned to service at block 235 where another workpiece is processed, for example with substantially the same process as employed at block 210. Methods 200 may then be iterated any number of times. Although for simplicity, methods 200 may be performed without the assistance of spare components, a practical implementation may involve the use of spares where the chamber component received at block 220 was taken from a spares supply to more quickly return the processing chamber to workpiece production. The chamber component removed at block 215 may then be cleaned in accordance with embodiments described herein to replenish the spares supply in preparation for another iteration of methods 200.

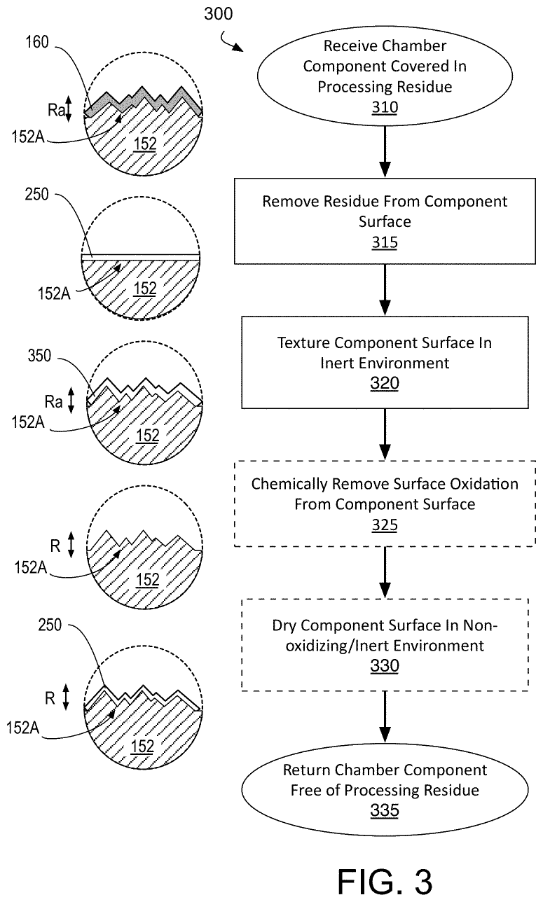

FIG. 3 is a flowchart depicting methods 300 for reconditioning a reactive process chamber component, in accordance with some embodiments. Methods 300 may be practiced by a user of a processing chamber 100 (FIG. 1), for example. Alternatively, another entity, such as a parts refurbishment vendor, may practice methods 300. FIG. 3 also illustrates an exemplary component surface evolving as methods 300 are practiced on edge-ring 152.

Methods 300 begin at input 310 with receipt of a chamber component contaminated with processing residue, for example as a result of use in a reactive processing chamber. In the example further illustrated, edge-ring 152 has a textured edge-ring surface 152A covered with residue 160. A surface oxide (not depicted) may also be between surface 152A and residue 160.

At block 315, processing residue is removed from the component surface(s). One or more cleaning processes may be employed at block 315 depending on the composition and/or amount of residue present. In some exemplary embodiments where residue 160 comprises both aluminum and fluorine (e.g., as AlF), cleaning at block 315 may involve a highly mechanical removal technique such as lapping or polishing to physically strip residue 160. The polishing may use any suitable polishing pad and/or grit material, and may use any polishing pattern (e.g., jitterbug, etc.). A wet chemical removal process, potentially accompanied by ultrasonic energy, might also be utilized in combination with, or in the alternative to, lapping or polishing. The wet chemical clean may, for example, remove any amount residue that survives polishing. Any wet chemical clean known to be suitable for removing a particular residue from a particular component composition may be employed. For example, where the component is uncoated bulk aluminum, the chemical clean may entail an aqueous aluminum “pickle” bath including one or more low pH acids.

The mechanical cleaning performed at block 315 may have an impact on the chemical composition of the cleaned component surface. The chemical cleaning performed at block 315 may also impact the surface morphology of the cleaned component. For example, lapping/polishing can be expected to remove surface oxidation and mechanically deform the underlying bulk (e.g., aluminum) of the component. Although a chemical clean need not be practiced, such a clean may also change the surface composition, for example by dissolving an oxygen-rich passivation from the component. This may occur where the cleaning chemistry has low selectivity between the process residue (e.g., AlF) and the bulk (e.g., Al) or native passivation (e.g. AlₓO_{y}). In the example shown, edge-ring surface 152A is clean of residue and polished (i.e., untextured). For embodiments where edge-ring 152 is of a bulk metal (e.g., substantially pure Al) that spontaneously oxidizes in the presence of oxygen in the ambient environment, surface oxide 250 forms on the polished component surface.

Methods 300 continue with a reconditioning of the cleaned component surface. In exemplary embodiments, reconditioning includes at least a texturing of the component surface at block 320. The texturing is advantageously performed in an “inert” environment that controls oxygen contamination of the component. Although the texturing process may be expected to induce some surface oxidation of a component comprising a bulk metal that spontaneously oxidizes in the presence of any oxygen, the inert texturing process environment may be controlled so as to minimize oxygen contamination, for example so it can be more readily removed without also losing much of the texture created at block 320.

In some embodiments, one or more surfaces of a chamber component is subjected to media blasting where the chamber component is placed in a media blasting system, for example within an enclosure or cabinet. The media may be selected to be more or less aggressive, for example ranging from soda to larger media grits (e.g., glass beads of any suitable diameter, garnet, alumina grit, etc.). A media blasting process may be tuned to achieve a desired level of component surface texture. Embodiments herein are to advantageously reduce the rate of component surface oxidation during the media blasting process. The inventors have found that surface oxidation rates are quite high if natural air is employed as a media propellant and/or natural air is present in the blasting cabinet as the component temperature increases from the impinging media. The presence of molecular oxygen (O₂) in natural air will induce significant oxygen contamination through oxidation (e.g., AlOₓ) of the component surface (e.g., Alₓ). The oxidation may be driven, at least in part, by frictional heating of the component associated with the blasting process. Hence, advantageous embodiments reduce the level of O₂, and more generally the amount oxygen (e.g., also in the form of moisture) in the media blasting environment.

In some exemplary embodiments, before media blasting is initiated, the cabinet in which the component is placed may be first purged of natural air. The media blasting cabinet is advantageously isolated from the natural air environment through some over pressure of an inert gas. For example, the cabinet may be purged with a gas having a smaller fraction of O₂ than natural air, such as high purity N₂. Another inert gas such as Ar, He, Kr, or Xe, may also be used. In still other embodiments, a reducing environment may be established for the media blasting process. For example, a forming gas, such as He:H₂(<5%) may be introduced into an isolated media blasting atmosphere. Depending on the architecture of the media blasting system, other components of the blasting system may also be purged of oxygen prior to media blasting a component surface. For example, cabinet gas lines, media supply, gun, etc. may all be purged before initiating component surfacing. In some advantageous embodiments, the media is also purged with an inert (non-oxidizing) gas, such as N₂, for example to minimize oxygen contaminants within the media supply during storage between uses.

In some further embodiments, during the blasting process the media is propelled with a gaseous propellant having a smaller fraction of O₂ than natural air (e.g., less than 21% by volume). In some advantageous embodiments, the media is propelled with an inert (non-oxidizing) propellant, such as N₂. For reasonable cost, a high pressure N₂ propellant may be supplied at a purity of at least 95%. Higher purities (e.g., 98%, 99%, 99.95%, etc.) may also be employed, if available. For example, a dewar of liquid N₂ may be coupled to an evaporator to provide high purity N₂ (e.g., exceeding 99%). While N₂ has been found to be capable of producing good results at low cost, other inert gaseous propellants, such as, but not limited to Ar, He, Kr, or Xe, may also be used to propel the media either in combination with N₂ or as an alternative to N₂.

In addition to removing O₂ from the media blasting process, moisture sources and/or moisture levels within a media blasting system may also be reduced to further lower the level of oxygen available to react with the component surface during the blasting process. For example, blasting media may be dried to reduce its moisture content prior to propelling it against a chamber component surface. Media drying may be through the application of heat (e.g., 100° C., or more) and/or through an inert gas (e.g., N₂, Ar, He, Kr, Xe, or He:H₂) purge. Any other drying agent known to be suitable for reducing moisture in a given media may also be employed. The gaseous propellant may also be dried to a low moisture level (e.g., <3%, <1%, <5 ppm water vapor, etc.).

Following media blasting, a component surface will have some level of texture (e.g., roughness value). For example, the component surface may have an average roughness value Rₐ in the range of 40-250 pin. Before being reintroduced to natural air the component may be allowed to cool (e.g., to room temperature) within the inert (e.g., N₂ purged) blasting environment to avoid thermally enhancing the surface oxidation rate of ambient air. At this point, component surface 152A can be expected to have a surface oxide 350 within which the atomic concentration of oxygen exceeds that of the bulk metal (e.g., Alₓ). However, below some surface depth, the atomic concentrations of the bulk metal constituent and oxygen cross with the atomic concentration of the bulk metal becoming greater than that of oxygen.

Depending on the extent of oxygen contamination, methods 300 may continue at block 325 where a chemical surface de-oxidation is performed. In FIG. 3, block 325 is illustrated as a dashed line box to emphasize that block 325 is optional. The chemistry employed at block 325 may be any known to be suitable for the chemical composition of the particular surface oxide present. In accordance with some embodiments, an aluminum (Alₓ) component may be processed in a wet chemical deoxidation bath suitable for removing AlOₓ). The wet chemical deoxidation batch may include, for example, ferric sulfate and nitric acid. Other deoxidation processes (e.g., chromic acid or hydrofluoric acid for aluminum components) may also be employed in combination, or in the alterative, so as to similarly leave an activated bare metal surface 152A having a texture that may result from both the texturing at block 320 and the de-oxidation at block 325.

Notably, by minimizing the extent of surface oxidation induced by the surfacing process, the chemical deoxidation will not greatly reduce surface texture, and may even increase texture slightly. This ability to recover an activated metal surface having the desired level of texture is one benefit of practicing non-oxidizing/inert media blasting at texturing block 320.

Methods 300 continue at block 330 where the component surface is dried. Drying at block 330 may be practiced for those embodiments where a wet chemical deoxidation is practiced at block 325. In advantageous embodiments, the drying is performed in an environment that again limits surface oxidation of the component so as to arrive at a surface oxide that is well matched to that of a new/unused component surface.

In some embodiments, block 330 comprises a heated oven dry or, “bake” in an atmosphere having a having a smaller fraction of O₂ than air. Advantageously, the bake/dry is performed in a substantially inert atmosphere, such as high purity N₂ (e.g., >95%). For example, in some implementations the chamber component is placed in an oven enclosure. The oven may be first purged of natural air with an overpressure of high-purity inert gas (e.g., N₂). Alternatively, a reducing gas, such as a forming gas, may be introduced into the drying oven. The oven may then be heated (e.g., to at least 100° C.) to evaporate any moisture remaining on the component from the deoxidation process. The oven temperature may then be reduced to near ambient room temperature, the N₂ purge then discontinued, and the cooled component removed from the oven. Queue time between deoxidation and the dry may be minimized to avoid excessive and/or inconsistent surface oxidation at ambient atmospheric conditions.

As further illustrated in FIG. 3, the clean and reconditioned component surface 152A has some target roughness value Ra, which may be, for example at least as rough as a new component. Component surface 152A has a surface oxide 250 that may be approximately the same as the surface oxide found on a new component (e.g., has greater concentration of oxygen than aluminum, has 45 at. % of O, or more, etc.). In the illustrated example, surface oxide 250 has an oxygen concentration lower than that surface oxide 350 generated by the texturing process.

Methods 300 complete at block 335 where the reconditioned chamber component may be returned to its source (e.g., a reactive processing chamber, a spares supply, a supply chain customer, etc.).

As noted above, AES and/or X-ray photoelectron spectroscopy (XPS) may be employed to characterize the extent of surface oxygen contamination induced during refurbishment of a chamber component. For such analyses, AES and/or XPS may be combined with ion beam sputtering to determine an atomic composition-depth profile. Quantitative sputter rates may be determined for a given component composition and milling ion (e.g., Ar+) to convert a sputter time axis into a depth profile.

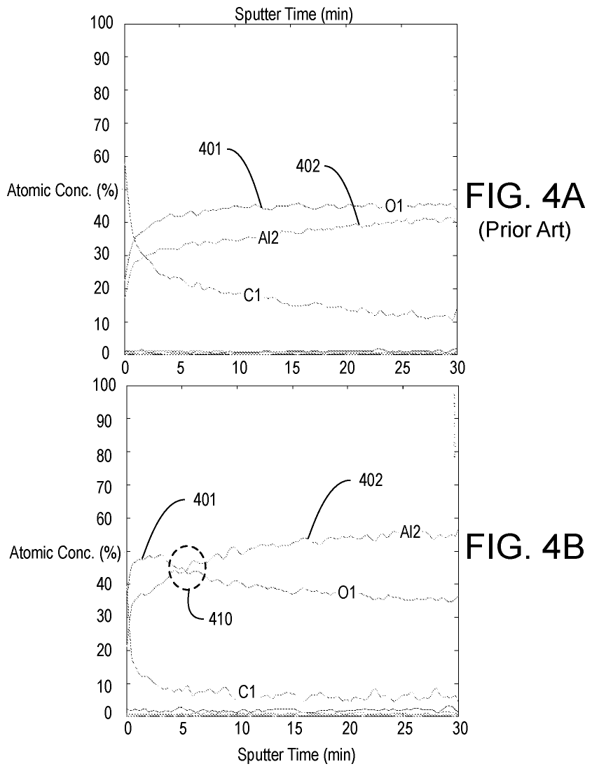

FIG. 4A illustrates an AES composition profile depicting the concentration of various elements, including atomic oxygen (O) atomic percentage 401 and aluminum atomic percentage 402 for an exemplary Alₓ component refurbished through a conventional residue clean and resurfacing process. As shown in FIG. 4A, upon initiating the sputter at time 0, the oxygen at. % is higher than the aluminum at. %. This relationship between oxygen and aluminum at. % remains true even for relatively long sputter times of up to 30 minutes. As further shown, oxygen increases with sputter time (depth from surface) until becoming nearly constant at >40 at. % while aluminum slowly trends upward toward 40 at. %, but never exceeds the O at. %.

In contrast, FIG. 4B illustrates an AES profile depicting oxygen atomic percentage 401 and aluminum atomic percentage 402 for an exemplary Alₓ component refurbished through a residue clean and resurfacing process in accordance with methods 300 (FIG. 3). For the specific example illustrated, all blocks of methods 300 have been performed (including blocks 325 and 330). As shown in FIG. 4B, at sputter time 0, the oxygen at. % is again higher than the aluminum at. %, but at a sputter time of around 5 minutes, there is a cross-over point 410 where the oxygen at. % falls below the aluminum at. % (e.g., at about 45 at. %). With longer sputter times, oxygen continues to decline toward about 30 at. % as aluminum trends up to over 50 at. %. Hence, at a depth from the surface corresponding to cross-over point 410, the component transitions from a surface oxide comprising less aluminum than oxygen to a predominantly aluminum bulk. The actual depth associated with the cross-over point can be determined based on parameters of the analysis. For example, where 2×2 mm 1 nA Ar+ sputter beam is employed for an Auger profile, the sputter rate of a reference PVD Al₂O₃ film may be estimated as approximately 12 Angstroms/min. Considering PVD films typically have less topography (texture) than the conditioned surface of a process chamber component, crossover point 410 where oxygen at. % falls below the aluminum at. % is estimated to be less than 5 nm. Oxygen contamination of the component is therefore quantitatively distinct for the residue clean and resurfacing processes disclosed herein.

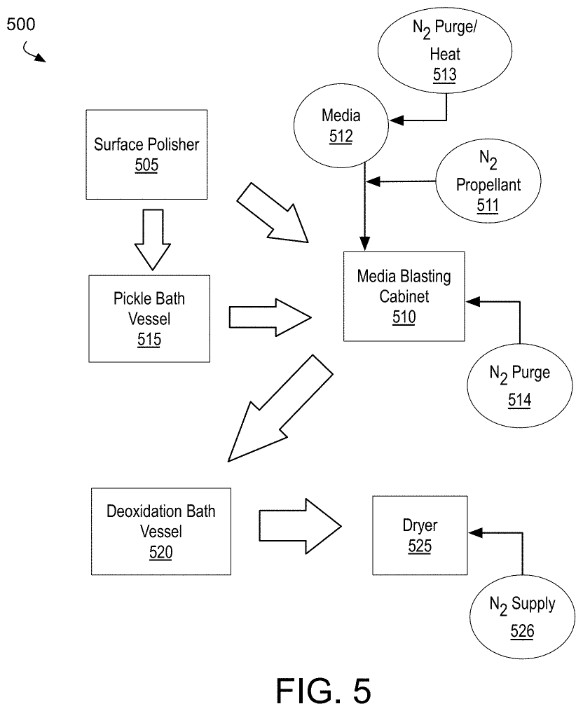

FIG. 5 illustrates an exemplary process chamber component reconditioning system 500 suitable for implementing methods 300, in accordance with some embodiments. As shown, reconditioning system 500 includes a surface polisher 505, a media blasting cabinet 510, a pickle bath vessel 515, a deoxidation bath vessel 520, and a dryer 525. Various ones of the processing modules of system 500 may be employed to implement particular ones of methods 300. For example, surface polisher 505 may be any commercially available polisher suitable for the form factor of the chamber component to be cleaned. Surface polisher 505 may be operated in any manner known to be suitable for removing a residue comprising one or more chemical byproducts including aluminum and fluorine from at least a portion of the component surface.

From surface polisher 505, the component may be transferred first to pickle bath vessel 515, or directly to media blasting cabinet 510. Pickle bath vessel 515 is to hold any suitable pickle liquor that may be optionally employed to remove any residue and/or contaminants remaining after surface polishing. Media blasting cabinet 510 may be any enclosure of sufficient size to accommodate blasting of the chamber component surface(s). In exemplary embodiments, media blasting cabinet 510 is coupled to an N₂ propellant 511, which may be any N₂ dewar and evaporator, or any N₂ generator capable of delivering high purity N₂ at flow rates/pressures adequate to convey a media from media supply 512 into blasting cabinet 510. In the illustrated example, media supply 512 is further coupled in fluid communication with an N₂ purge supply 513. Media supply 512 may also be heated, for example to reduce moisture contamination. Media blasting cabinet 510 is similarly coupled in fluid communication with an N₂ purge supply 514. In some embodiments, N₂ purge supply 513 may be the same as N₂ propellant supply 511 (e.g., both provided by a single N₂ generator). From media blasting cabinet 510, a chamber component may be transferred to deoxidation bath vessel 520 that holds a chemical to at least partially remove oxygen from at least the portion of the surface. From deoxidation bath vessel 520, a chamber component may be transferred to dryer 525. Dryer 525 is to dry at least a portion of the surface following exposure to the chemical deoxidation bath. Dryer 525 may be coupled to a gaseous supply having a smaller fraction of O₂ than air, such as N₂ supply 526. N₂ supply 526 may be the same as N₂ propellant supply 511 and/or N₂ purge supplies 513, 514 (e.g., all provided by a single N₂ generator), or the propellant supply may be an isolated high-pressure supply.

Accordingly, the controlled cleaning and treating of a chamber component may (i) remove the build-up of byproducts from the surface of the component, and (ii) recondition the cleaned part to have substantially the same surface morphology and surface oxidation as a new component. The reuse of refurbished chamber components may reduce workpiece processing costs. For example, refurbishment cost may be lower than buying new chamber component. Refurbishment may also improve supply line stability, as new components may not be readily available. Refurbishing and reusing a chamber component may occur repeatedly, for example until a thickness of the chamber component is eventually reduced to less than a lower thickness specification provided by a processing chamber manufacturer.

While certain features set forth herein have been described with reference to various implementations, the description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that this disclosure is not limited to the embodiments so described, but can be practiced with modification and alteration without departing from the scope of the appended claims. For example, the above embodiments may include specific combinations of features as further provided below.

In first examples, a method of conditioning a surface of a reactive processing chamber component comprises media blasting at least a portion of the surface with a gaseous media propellant comprising a smaller fraction of O₂ than air, and performing a chemical treatment that at least partially removes oxidation from at least the portion of the surface.

In second examples, for any of the first examples the propellant comprises predominantly one of N₂, Ar, He, Kr, Xe.

In third examples, for any of the first through second examples the propellant comprises N₂ at a purity of at least 95%.

In fourth examples, for any of the first through third examples the method further comprises polishing at least the portion of the surface prior to the media blasting.

In fifth examples, for any of the fourth examples the polishing at least partially removes a residue comprising one or more chemical byproducts of a process performed in the chamber.

In sixth examples, for any of the fifth examples the component comprises aluminum and the residue comprises aluminum and fluorine.

In seventh examples, for any of the first through sixth examples the chemical treatment comprises an aqueous acid clean, and the method further comprises drying at least the portion of the surface following the chemical treatment, and wherein the drying is performed within an environment comprising less O₂ than air.

In eighth examples, for any of the seventh examples the drying is performed within an environment of N₂ at a purity of at least 95%.

In ninth examples, for any of the first through eighth examples the method further comprises drying the media through an application of heat or dry gas comprising less O₂ than natural air.

In tenth examples, for any of the first through ninth examples n an aluminum at. % is less than an oxygen at. % within a surface oxide of the component, and, within a bulk of the component, the aluminum at. % is greater than the oxygen at. %.

In eleventh examples, for any of the tenth examples the oxygen at. % is equal to the aluminum at. % at some point within an auger electron spectroscopy (AES) profile for a sputter time less than 15 minutes.

In twelfth examples, for any of the eleventh examples the oxygen at. % equals the aluminum at. % at a depth less than 5 nm from a surface of the component.

In thirteenth examples, for any of the tenth through twelfth examples the surface oxide comprises more than 45 at. % O, and the bulk comprises more than 50 at. % Al.

In fourteenth examples, a method of operating an etch process chamber comprises positioning a first workpiece adjacent to an edge ring within the chamber, the edge ring comprising a predominantly aluminum bulk and a surface oxide upon the bulk and the surface oxide comprising less aluminum than oxygen. The method comprises performing an etch process on the first workpiece within the chamber, the etch process forming a residue comprising one or more chemical byproducts of the etch process upon edge ring. The method comprises removing the edge ring from the chamber. The method comprises receiving the edge ring subsequent to a refurbishment, the edge ring substantially free of the residue, comprising the predominantly aluminum bulk and a surface oxide comprising less aluminum than oxygen. The method comprises returning the edge ring to the chamber, and performing an etch process on a second workpiece after returning the edge ring to the chamber.

In fifteenth examples, for any of the fourteenth examples prior to performing the etch process on the first workpiece, the component surface has a first average roughness value greater than 25 μin, and wherein subsequent to the refurbishment the component surface has a second average roughness value that is within a predetermined threshold of the first average roughness value.

In sixteenth examples, for any of the fifteenth examples the second roughness value is at least equal to 40 μin.

In seventeenth examples, for any of the fifteenth through sixteenth examples performing the etch process further comprises energizing a plasma remote from the chamber, and wherein the residue comprises aluminum and fluorine.

In eighteenth examples, for any of the fourteenth through seventeenth examples the refurbishment reduces a thickness of the edge ring, and wherein the method further comprises repeatedly performing the removing, the receiving, and the returning of the edge ring until the thickness of the edge ring falls below a predetermined threshold.

In nineteenth examples, a process chamber component reconditioning system comprises an enclosure within which at least a portion of a surface of a reactive process chamber component is to be exposed to a media propelled with a gaseous propellant. The system comprises a supply of the gaseous propellant, the supply coupled to an inlet of the enclosure, and the supply of the gaseous propellant comprising a smaller fraction of O₂ than air. The system comprises one or more vessels to contain a chemical bath to at least partially remove oxygen from at least the portion of the surface.

In twentieth examples, for any of the nineteenth examples the supply of the gaseous propellant consists of N₂ having a purity of at least 95%.

In twenty-first examples, for any of the nineteenth through twentieth examples, the system further comprises a polisher to remove a residue from at least the portion of the surface, the residue comprising one or more chemical byproducts including fluorine.

In twenty-second examples, for any of the twenty-first examples the system includes a dryer to dry at least a portion of the surface following exposure to the chemical bath, and further comprising a gaseous supply coupled to the dryer, the gaseous supply having a smaller fraction of O₂ than air.

In twenty-third examples, for any of the twenty-second examples the gaseous supply coupled to the dryer consists of N₂ having a purity of at least 95%.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed.

We claim:

1. A method of conditioning a surface of a reactive processing chamber component, the method comprising:
media blasting at least a portion of the surface with a gaseous media propellant comprising a smaller fraction of O₂ than air; and
performing a chemical treatment that at least partially removes oxidation from at least the portion of the surface.

2. The method of claim 1, wherein the propellant comprises predominantly one of N₂, Ar, He, Kr, Xe.

3. The method of claim 2, wherein the propellant comprises N₂ at a purity of at least 95%.

4. The method of claim 1, further comprising polishing at least the portion of the surface prior to the media blasting.

5. The method of claim 4, wherein the polishing at least partially removes a residue comprising one or more chemical byproducts of a process performed in the chamber.

6. The method of claim 5, wherein the component comprises aluminum and the residue comprises aluminum and fluorine.

7. The method of claim 1, wherein the chemical treatment comprises an aqueous acid clean, and the method further comprises drying at least the portion of the surface following the chemical treatment, and wherein the drying is performed within an environment comprising less O₂ than air.

8. The method of claim 7, wherein the drying is performed within an environment of N₂ at a purity of at least 95%.

9. The method of claim 1, further comprising drying the media through an application of heat or dry gas comprising less O₂ than natural air.

10. The method of claim 1, wherein an aluminum at. % is less than an oxygen at. % within a surface oxide of the component, and wherein, within a bulk of the component, the aluminum at. % is greater than the oxygen at. %.

11. The method of claim 10, wherein the oxygen at. % is equal to the aluminum at. % at some point within an auger electron spectroscopy (AES) profile for a sputter time less than 15 minutes.

12. The method of claim 11, wherein the oxygen at. % equals the aluminum at. % at a depth less than 5 nm from a surface of the component.

13. The method of claim 10, wherein:
the surface oxide comprises more than 45 at. % O; and
the bulk comprises more than 50 at. % Al.

14. A method of operating an etch process chamber, the method comprising:
positioning a first workpiece adjacent to an edge ring within the chamber, the edge ring comprising a predominantly aluminum bulk and a surface oxide upon the bulk, wherein the surface oxide comprises less aluminum than oxygen;
performing an etch process on the first workpiece within the chamber, the etch process forming a residue comprising one or more chemical byproducts of the etch process upon edge ring;
removing the edge ring from the chamber;
receiving the edge ring subsequent to a refurbishment, the edge ring substantially free of the residue, and comprising the predominantly aluminum bulk and a surface oxide comprising less aluminum than oxygen;
returning the edge ring to the chamber; and
performing an etch process on a second workpiece.

15. The method of claim 14, wherein prior to performing the etch process on the first workpiece, the component surface has a first average roughness value greater than 25 μin, and wherein subsequent to the refurbishment the component surface has a second average roughness value that is within a predetermined threshold of the first average roughness value.

16. The method of claim 15, wherein the second roughness value is at least equal to 40 μin.

17. The method of claim 15, wherein performing the etch process further comprises energizing a plasma remote from the chamber, and wherein the residue comprises aluminum and fluorine.

18. The method of claim 14, wherein the refurbishment reduces a thickness of the edge ring, and wherein the method further comprises repeatedly performing the removing, the receiving, and the returning of the edge ring until the thickness of the edge ring falls below a predetermined threshold.

19. A process chamber component reconditioning system, comprising:
an enclosure within which at least a portion of a surface of a reactive process chamber component is to be exposed to a media propelled with a gaseous propellant;
a supply of the gaseous propellant, the supply coupled to an inlet of the enclosure, wherein the supply of the gaseous propellant comprises a smaller fraction of O₂ than air; and
one or more vessels to contain a chemical bath to at least partially remove oxygen from at least the portion of the surface.

20. The system of claim 19, wherein the supply of the gaseous propellant consists of N₂ having a purity of at least 95%.

21. The system of claim 19, further comprising a polisher to remove a residue from at least the portion of the surface, the residue comprising one or more chemical byproducts including fluorine.

22. The system of claim 19, further comprising a dryer to dry at least a portion of the surface following exposure to the chemical bath, and further comprising a gaseous supply coupled to the dryer, the gaseous supply having a smaller fraction of O₂ than air.

23. The system of claim 22, wherein the gaseous supply coupled to the dryer consists of N₂ having a purity of at least 95%.
